(19) United States
(12) Patent Application Publication
(10) Pub. No.: US 2026/0156812 A1
(43) Pub. Date: Jun. 4, 2026

(54) SEMICONDUCTOR DEVICE WITH PERIPHERAL CIRCUIT ON CELL SUBSTRATE

(71) Applicant: SAMSUNG ELECTRONICS CO., LTD., Suwon-si (KR)

(72) Inventors: Seunguk Han, Suwon-si (KR); Jinwoo Han, Suwon-si (KR)

(73) Assignee: SAMSUNG ELECTRONICS CO., LTD., Suwon-si (KR)

(21) Appl. No.: 19/226,805

(22) Filed: Jun. 3, 2025

(30) Foreign Application Priority Data
Nov. 29, 2024 (KR) 10-2024-0175842

(51) Int. Cl. H10B 12/00; G11C 5/06

(52) U.S. Cl. CPC H10B 12/50; G11C 5/06; H10B 12/482; H10B 12/488

(57) ABSTRACT

A semiconductor device includes a first substrate; a cell structure and a diode structure on the first substrate in a first direction parallel to a surface of the first substrate; a second substrate on the cell structure and the diode structure; a core circuit element on the second substrate and connected to the cell structure; and a peripheral circuit element connected to the diode structure, in which the cell structure includes: a cell semiconductor pattern, a bit line on one end of the cell semiconductor pattern, a capacitor on another end of the cell semiconductor pattern, and a word line adjacent to the cell semiconductor pattern, in which the diode structure includes: a diode semiconductor pattern, a first electrode on one end of the diode semiconductor pattern, a second electrode on another end of the diode semiconductor pattern, and a diode gate electrode adjacent to the diode semiconductor pattern.

### CROSS-REFERENCE TO RELATED APPLICATION

This application claims priority to and the benefit of Korean Patent Application No. 10-2024-0175842 filed at the Korean Intellectual Property Office on Nov. 29, 2024, the entire contents of which are incorporated herein by reference.

### BACKGROUND

### 1. Field

The present disclosure relates to a semiconductor device.

### 2. Description of Related Art

Currently, there is an increased demand to increase an integration of semiconductor devices. In a case of two-dimensional semiconductor devices, an integration is mainly determined by an area occupied by a unit memory cell. This aspect of the integration may be affected by a level of a fine pattern formation technology.

However, since the fine pattern formation technology requires expensive equipment, the integration of two-dimensional semiconductor devices is limited. Accordingly, 3-dimensional semiconductor memory devices having memory cells arranged 3-dimensionally are being proposed.

### SUMMARY

Embodiments are intended to provide a semiconductor device that can reduce the size of a semiconductor chip.

According to an aspect of the disclosure, a semiconductor device includes a first substrate; a cell structure and a diode structure on the first substrate in a first direction parallel to a surface of the first substrate; a second substrate on the cell structure and the diode structure; a core circuit element on the second substrate and connected to the cell structure; and a peripheral circuit element connected to the diode structure, wherein the cell structure comprises: a cell semiconductor pattern on the first substrate, a word line adjacent to the cell semiconductor pattern and extending in a second direction intersecting the first direction, the second direction parallel to the surface of the first substrate, a bit line on one end of the cell semiconductor pattern along the first direction and extending in a third direction perpendicular to the surface of the first substrate, and a capacitor on another end of the cell semiconductor pattern along the first direction,, wherein the diode structure comprises: a diode semiconductor pattern on the first substrate, a first electrode on one end of the diode semiconductor pattern along the first direction and extending in the third direction, a second electrode on another end of the diode semiconductor pattern along the first direction and extending in the third direction, and a diode gate electrode adjacent to the diode semiconductor pattern and extending in the second direction.

According to an aspect of the disclosure, a semiconductor device includes: a first substrate; a cell structure and a diode structure on the first substrate in a first direction parallel to a surface of the first substrate; a second substrate on the cell structure and the diode structure; a core circuit element on the second substrate and connected to the cell structure; and a peripheral circuit element connected to the diode structure, wherein the cell structure comprises: a memory cell on the first substrate, the memory cell comprising a cell semiconductor pattern, a bit line and a capacitor on the cell semiconductor pattern, and a word line adjacent to the cell semiconductor pattern, wherein the diode structure comprises: a diode on the first substrate, the diode comprising a diode semiconductor pattern, a first electrode and a second electrode on the diode semiconductor pattern, and a diode gate electrode adjacent to the diode semiconductor pattern, wherein a portion of the cell semiconductor pattern on the bit line and a portion of the cell semiconductor pattern on the capacitor include a same type of dopant, and wherein a portion of the diode semiconductor pattern on the first electrode and a portion of the diode semiconductor pattern on the second electrode include different types of dopant.

According to an aspect of the disclosure, a semiconductor device includes: a first substrate; a cell structure and a diode structure on the first substrate in a first direction parallel to a surface of the first substrate; a second substrate on the cell structure and the diode structure; a core circuit structure overlapping the cell structure on the second substrate; and a peripheral circuit structure overlapping the diode structure on the second substrate, wherein the cell structure comprises: a memory cell on the first substrate in the second direction, the memory cell comprising a cell semiconductor pattern, a bit line on one end of the cell semiconductor pattern along the first direction, a capacitor on another end of the cell semiconductor pattern along the first direction, and a word line adjacent to the cell semiconductor pattern and extending in a second direction intersecting the first direction, the second direction parallel to the surface of the first substrate, wherein the diode structure comprises: a diode on the first substrate, the diode comprising a diode semiconductor pattern, a first electrode on one end of the diode semiconductor pattern along the first direction, a second electrode on another end of the diode semiconductor pattern along the first direction, and a diode gate electrode adjacent to the diode semiconductor pattern and extending in the second direction, wherein the first electrode, the second electrode, and the diode gate electrode of the diode are connected to a static electricity discharge prevention circuit of the peripheral circuit structure.

According to embodiments, the size of the semiconductor chip may be reduced.

### BRIEF DESCRIPTION OF DRAWINGS

FIG. 1 is a schematic view of a semiconductor device according to one or more embodiments.

FIG. 2 is a schematic perspective view of a cell structure of a semiconductor device according to one or more embodiments.

FIG. 3 is a cross-sectional view of a semiconductor device according to one or more embodiments taken along a line A-A′ of FIG. 2.

FIG. 4 is a cross-sectional view of a semiconductor device according to one or more embodiments taken along a line B-B′ of FIG. 2.

FIG. 5 is a schematic perspective view of a diode structure of a semiconductor device according to one or more embodiments.

FIG. 6 is a cross-sectional view of a semiconductor device according to one or more embodiments taken along a line C-C′ of FIG. 5.

FIG. 7 is a cross-sectional view of a semiconductor device according to one or more embodiments taken along a line D-D′ of FIG. 5.

FIG. 8 is a schematic perspective view of a diode structure of a semiconductor device according to one or more embodiments.

FIG. 9 is a schematic perspective view of a diode structure of a semiconductor device according to one or more embodiments.

FIG. 10 is a cross-sectional view of a diode structure according to one or more embodiments taken along a line E-E′ of FIG. 9.

FIG. 11 is a cross-sectional view of a diode structure according to one or more embodiments.

FIG. 12 is a schematic perspective view of a diode structure of a semiconductor device according to one or more embodiments.

FIG. 13 is a cross-sectional view of a diode structure according to one or more embodiments taken along a line F-F′ of FIG. 12.

### DETAILED DESCRIPTION

The present disclosure will be described more fully hereinafter with reference to the accompanying drawings, in which exemplary embodiments of the disclosure are shown. As those skilled in the art would realize, the described embodiments may be modified in various different ways, all without departing from the spirit or scope of the present disclosure.

Descriptions of parts not related to the present disclosure are omitted, and like reference numerals designate like elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

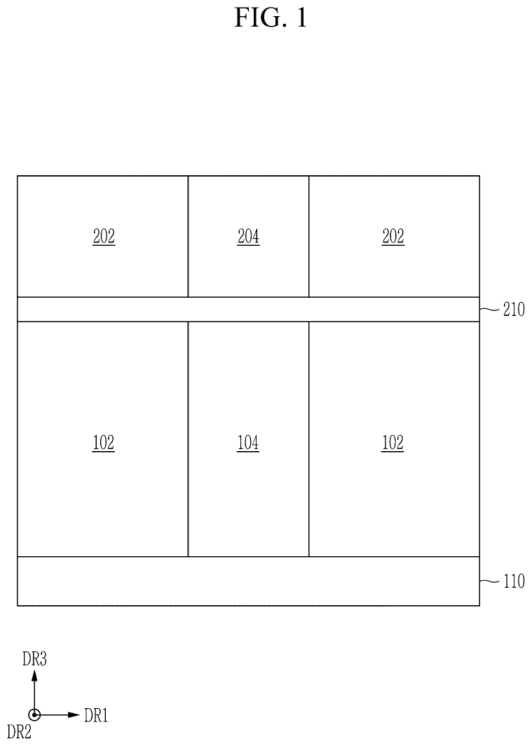

Hereinafter, a semiconductor device according to one or more embodiments is described with reference to FIG. 1 to FIG. 7.

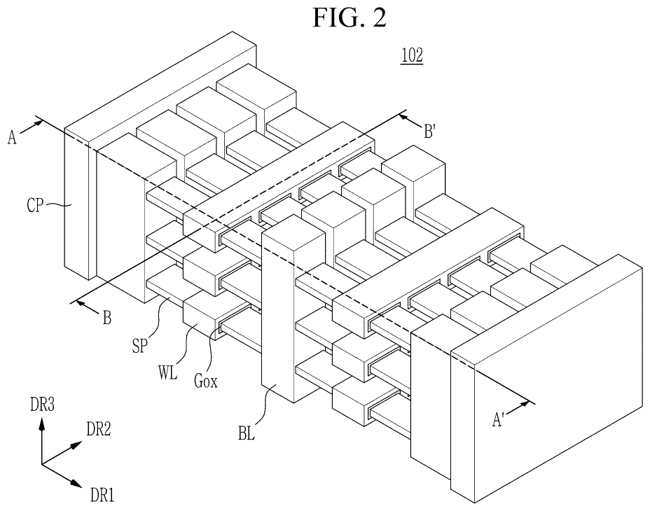

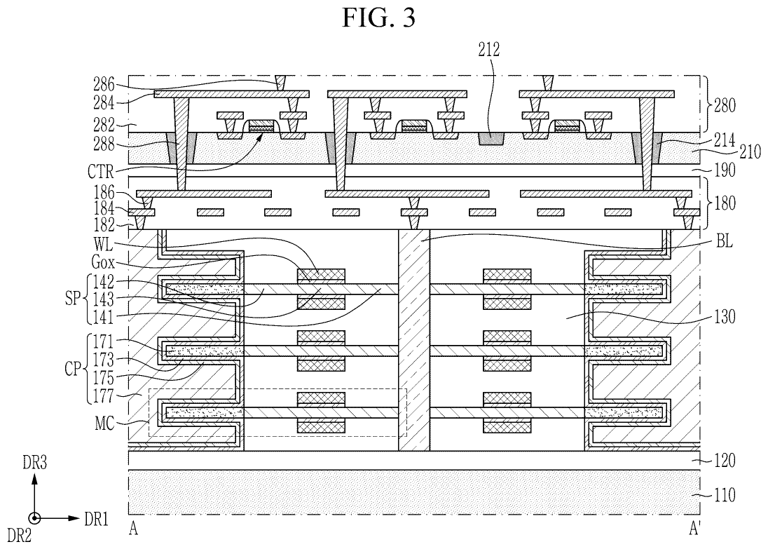

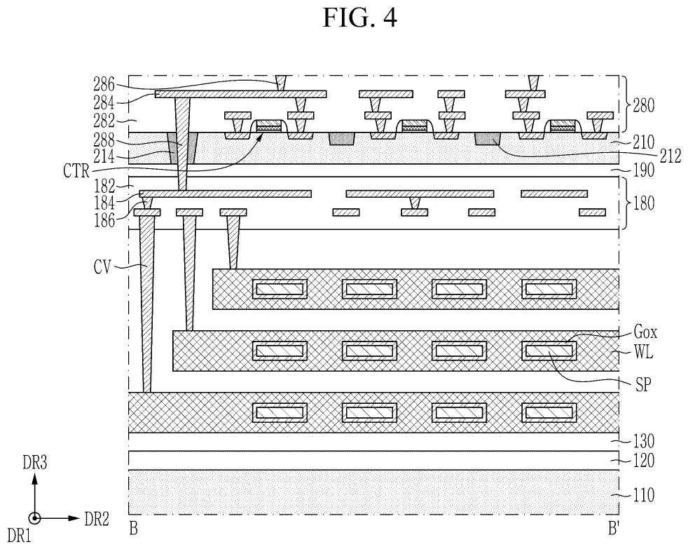

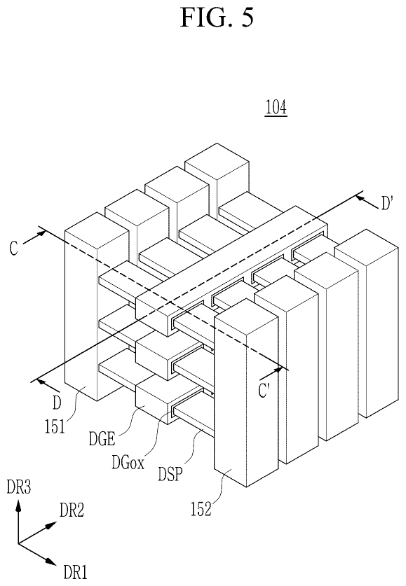

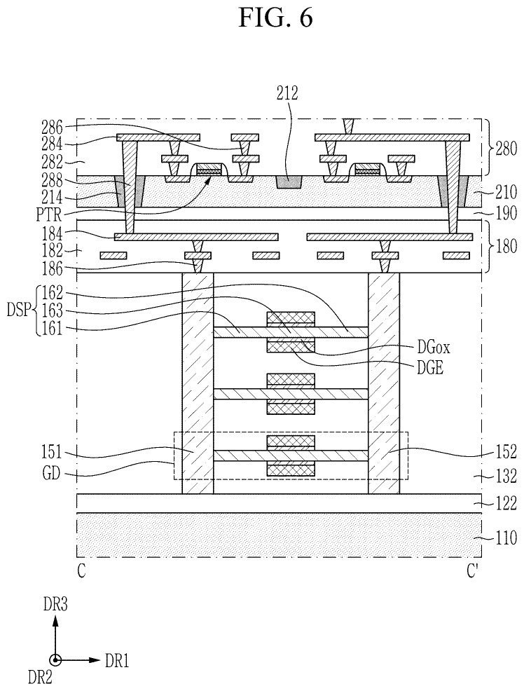

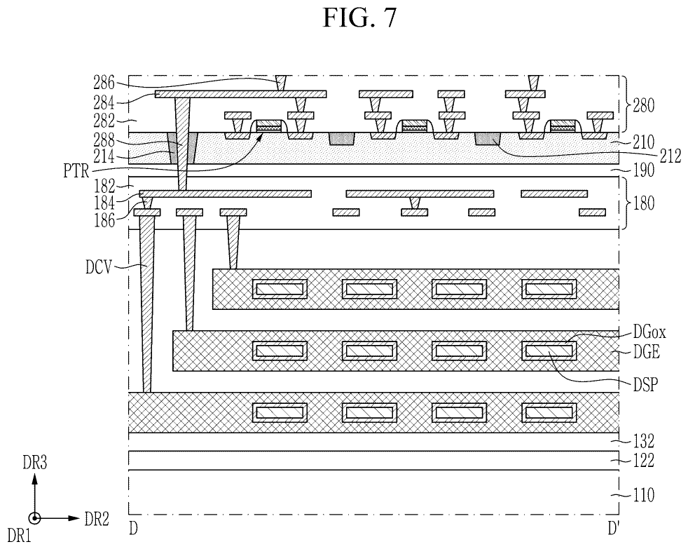

FIG. 1 is a schematic view of a semiconductor device according to one or more embodiments. FIG. 2 is a schematic perspective view of a cell structure of a semiconductor device according to one or more embodiments. FIG. 3 is a cross-sectional view of a semiconductor device according to one or more embodiments taken along a line A-A′ of FIG. 2. FIG. 4 is a cross-sectional view of a semiconductor device according to one or more embodiments taken along a line B-B′ of FIG. 2. FIG. 5 is a schematic perspective view of a diode structure of a semiconductor device according to one or more embodiments. FIG. 6 is a cross-sectional view of a semiconductor device according to one or more embodiments taken along a line C-C′ of FIG. 5. FIG. 7 is a cross-sectional view of a semiconductor device according to one or more embodiments taken along a line D-D′ of FIG. 5.

Referring to FIG. 1, a semiconductor device according to one or more embodiments may include a first substrate 110, a cell structure 102 and a diode structure 104 positioned on the first substrate 110, a second substrate 210 positioned on the cell structure 102 and the diode structure 104, and a core circuit structure 202 and a peripheral circuit structure 204 positioned on the second substrate 210.

In one or more embodiments, the cell structure 102 and the diode structure 104 may be arranged in a parallel direction on the upper surface of the first substrate 110. For example, the cell structure 102 and the diode structure 104 may be arranged in first direction DR1, but the embodiments are not limited thereto. The diode structure 104 may also be arranged with the cell structure 102 in the second direction DR2. The second direction DR2 is a direction parallel to the upper surface of the first substrate 110 and may be a direction intersecting the first direction DR1. For example, the second direction DR2 may be a direction orthogonal to the first direction DR1. Furthermore, a third direction DR3 (e.g., vertical direction) may be orthogonal to the first direction DR1 and the second direction DR2. As understood by one of ordinary skill in the art, reference to the directions DR1, DR2, and DR3 as first, second, and third directions is interchangeable. For example, DR1 may be referred to as a first direction, DR2 may be referred to as a second direction perpendicular to the first direction, and DR3 may be referred to as a third direction perpendicular to the first direction and the second direction. In another example, DR1 may be referred to as a first direction, DR3 may be referred to as a second direction perpendicular to the first direction, and DR2 may be referred to as a third direction perpendicular to the first direction and the second direction.

In one or more embodiments, a plurality of cell structures 102 may be positioned on the first substrate 110. The diode structure 104 may be positioned between two adjacent cell structures 102. FIG. 1 illustrates one diode structure 104 positioned on the first substrate 110, but the embodiments are not limited thereto. For example, a plurality of diode structures 104 may be positioned on the first substrate 110. In this case, each of the plurality of diode structures 104 may be positioned between two adjacent cell structures 102 forming an alternating series of a cell structure 102 and a diode structure 104. In one or more examples, the plurality of diode structures 104 may be positioned between two adjacent cell structures 102.

In one or more embodiments, the second substrate 210 may be positioned on the upper surface of the cell structure 102 and the diode structure 104. The second substrate 210 may completely cover the upper surface of the cell structure 102 and the diode structure 104. The cell structure 102 and the diode structure 104 may be positioned between the first substrate 110 and the second substrate 210. The cell structure 102 and the diode structure 104 may be positioned between the upper surface of the first substrate 110 and the lower surface of the second substrate 210.

In one or more embodiments, the core circuit structure 202 and the peripheral circuit structure 204 may be arranged on the second substrate 210 in a parallel direction on the upper surface of the second substrate 210. The core circuit structure 202 may overlap the cell structure 102 in a vertical direction (e.g., a third direction DR3) to the upper surface of the second substrate 210. The peripheral circuit structure 204 may overlap the diode structure 104 in the third direction. The arrangement of the core circuit structure 202 and the peripheral circuit structure 204 on the second substrate 210 may be substantially the same as the arrangement of the cell structure 102 and the diode structure 104 on the first substrate 110. For example, the core circuit structure 202 and the peripheral circuit structure 204 may be placed in first direction DR1, but the embodiments are not limited thereto. The peripheral circuit structure 204 may be arranged with the core circuit structure 202 in the second direction DR2.

In one or more embodiments, the plurality of core circuit structures 202 may be positioned on the second substrate 210. The peripheral circuit structure 204 may be positioned between two adjacent core circuit structures 202. FIG. 1 illustrates one peripheral circuit structure 204 positioned on the second substrate 210, but the embodiments are not limited thereto. For example, the plurality of peripheral circuit structures 204 may be positioned on the second substrate 210. In this case, each of the plurality of peripheral circuit structures 204 may be positioned between two adjacent core circuit structures 202. In one or more examples, the plurality of peripheral circuit structures 204 may be positioned between two adjacent core circuit structures 202 forming an alternating series of a core circuit structure 202 and a peripheral circuit structure 204.

Referring to FIG. 2 to FIG. 7, the cell structure 102 may include a plurality of memory cells MC stacked on the first substrate 110. The diode structure 104 may include a plurality of diodes GD stacked on the first substrate 110. The core circuit structure 202 may include a core circuit element CTR connected to the cell structure (e.g, 102, or the plurality of memory cells MC). The core circuit element CTR may overlap the cell structure 102 in the third direction DR3. The peripheral circuit structure 204 may include a peripheral circuit element PTR connected to the diode structure (104, or a plurality of diodes GD). The peripheral circuit element PTR may overlap the diode structure 104 in the third direction DR3.

The cell structure 102 and the core circuit structure 202 are described with reference to FIG. 2 to FIG. 4.

The cell structure 102 may include a plurality of cell semiconductor patterns SP stacked on the first substrate 110, a bit line BL in contact with one end of each of the plurality of cell semiconductor patterns SP along the first direction DR1 and extending in a vertical direction to the upper surface of the first substrate 110, a capacitor CP in contact with the other end of the cell semiconductor patterns SP along the first direction DR1, and a word line WL adjacent to the cell semiconductor patterns SP and extending in a second direction DR2 intersecting the first direction DR1.

The first substrate 110 may include a semiconductor material. For example, the first substrate 110 may include a Group IV semiconductor, a Group III-V compound semiconductor, a Group II-VI compound semiconductor, etc. For example, the first substrate 110 may include a semiconductor such as Si, Ge, or a compound semiconductor such as SiGe, SiC, GaAs, InAs, or InP. For example, the first substrate 110 may be a monocrystalline epitaxial layer grown on a monocrystalline silicon substrate. However, the material of the first substrate 110 is not limited thereto and may be changed in various ways.

The cell structure 102 may further include a lower insulation layer 120 positioned over the first substrate 110. The lower insulation layer 120 may include, for example, silicon oxide, silicon nitride, or silicon oxynitride, or a combination thereof.

The plurality of cell semiconductor patterns SP may be stacked on the lower insulation layer 120. The plurality of cell semiconductor patterns SP may be arranged spaced apart in the third direction DR3 on the lower insulation layer 120. The plurality of cell semiconductor patterns SP spaced apart and arranged in the third direction DR3 may be connected by the bit line BL. The plurality of cell semiconductor patterns SP may be arranged spaced apart in the first direction DR1 and the second direction DR2 in the same layer. The plurality of cell semiconductor patterns SP spaced apart and arranged in the first direction DR1 may be connected by the bit line BL. The plurality of cell semiconductor patterns SP spaced apart and arranged in the second direction DR2 may be covered by the word line WL extending in the second direction DR2. Each cell semiconductor pattern SP may include one or more circuit elements. In one or more examples, each cell semiconductor pattern SP in the plurality of cell semiconductor patterns may be identical. In one or more examples, at least one cell semiconductor pattern SP in the plurality of cell semiconductor patterns may have a different shape or different circuit elements than the other cell semiconductor patterns.

The cell semiconductor pattern SP may include a semiconductor material. For example, the cell semiconductor pattern SP may include silicon, germanium, or silicon-germanium. For example, the cell semiconductor pattern SP may include monocrystalline silicon or polycrystalline silicon.

The cell semiconductor pattern SP may be extended in the first direction DR1. The cell semiconductor pattern SP may have a rod or pillar shape. For example, the cell semiconductor pattern SP may have a square pillar shape, but the embodiments are not limited thereto. One end of the cell semiconductor pattern SP along the first direction DR1 may come into contact with the bit line BL. The other end of the cell semiconductor pattern SP along the first direction DR1 may be in contact with the capacitor CP.

The cell semiconductor pattern SP may include a first doping region 141 in contact with the bit line BL, a second doping region 142 in contact with the capacitor CP, and a channel region 143 positioned between the first doping region 141 and the second doping region 142. The first doping region 141 and the second doping region 142 may include p type or n type dopants. In one or more embodiments, the first doping region 141 and the second doping region 142 may include the same type of dopant. The channel region 143 may be an intrinsic semiconductor. For example, the channel region 143 may be an undoped or low concentration doped semiconductor. For example, the channel region 143 may include no dopant or may include a small amount of dopant. As understood by one of ordinary skill in the art, the channel region may be a region where current flow is controlled by a gate voltage. For example, the first doping region 141 may be a source region of a transistor, and the second doping region 142 may be a drain region of the transistor, where the channel region 143 enables conductivity between the two regions.

The channel region 143 may be a region that overlaps the word line WL. In one or more embodiments, the channel region 143 may overlap the word line WL in the third direction DR3 and the second direction DR2. The faces facing the third direction DR3 of the channel region 143 and the faces facing thereof in the second direction DR2 may be surrounded by the word line WL. The semiconductor device according to one or more embodiments may have a gate-all-around structure in which the entire surface of the channel region 143 of the cell semiconductor pattern SP is surrounded by the word line WL. However, the embodiment is not limited thereto. The semiconductor device according to one or more embodiments may have a double gate structure including two word lines WL each covering the faces of the channel region 143 facing in the third direction DR3. In one or more examples, the channel region 143 may overlap the word line WL in the third direction DR3, but may not overlap it in the second direction DR2. In this case, the same voltage or different voltages may be applied to the two word lines WL. When different voltages are applied to two word lines WL, one of two word lines WL may be used as a front gate and the other may be used as a back gate.

The cell structure 102 may include an interlayer insulating layer 130 positioned between the plurality of cell semiconductor patterns SP spaced apart and arranged in the third direction DR3. For example, the interlayer insulating layer 130 may include silicon oxide, silicon nitride, or silicon oxynitride, or a combination thereof, but the embodiments are not limited thereto.

The bit line BL may be extended to the third direction DR3 on the first substrate 110. The bit line BL may have a column shape. For example, the bit line BL may be a square column shape, but the embodiments are not limited thereto. For example, the bit line BL may be any suitable shape known to one of ordinary skill in the art. In one or more embodiments, a lower insulation layer 120 may be positioned between the bit line BL and the first substrate 110. The bit line BL may be insulated from the first substrate 110 by the lower insulation layer 120.

The bit line BL may be in contact with one end of the cell semiconductor pattern SP along the first direction DR1. The bit line BL may be in contact with the first doping region 141 of the cell semiconductor pattern SP. The bit line BL may be in contact with one end of the plurality of cell semiconductor patterns SP stacked in the third direction DR3 along the first direction DR1. The plurality of cell semiconductor patterns SP stacked in the third direction DR3 may be connected to the same bit line BL.

The cell structure 102 may include a plurality of bit lines BL. The plurality of bit lines BL may be spaced apart and arranged along the second direction DR2. In one or more examples, the plurality of bit lines BL may be further spaced and arranged along the first direction DR1.

The bit line BL may include a conductive material. The bit line BL may include, for example, a doped semiconductor material, a conductive metal nitride, a metal, a metal-semiconductor compound, or a combination thereof, but the embodiments are not limited thereto.

The word line WL may be positioned on both sides of the cell semiconductor pattern SP. In one or more embodiments, the word line WL may be positioned on both sides of the cell semiconductor pattern SP along the third direction DR3 and on both sides along the second direction DR2. The word line WL may be positioned on the upper surface, the lower surface, and both sides of the cell semiconductor pattern SP along the second direction DR2. The word line WL may surround the channel region 143 of the cell semiconductor pattern SP.

The word line WL may extend in a direction intersecting the cell semiconductor pattern SP. The word line WL may be extended in the second direction DR2. The word line WL may cover the plurality of cell semiconductor patterns SP that are spaced apart and arranged in the second direction DR2. In one or more embodiments, the word lines WL may surround the plurality of cell semiconductor patterns SP that are spaced and arranged apart in the second direction DR2. In one or more examples, the word line WL may overlap the plurality of cell semiconductor patterns SP spaced apart in the second direction DR2 in the second direction DR2 and third direction DR3. According to the embodiment, the word line WL may cover one side of the plurality of cell semiconductor patterns SP that are spaced apart in the second direction DR2 along the third direction DR3. In one or more examples, the word line WL may overlap the plurality of cell semiconductor patterns SP that are spaced apart in the second direction DR2 in the third direction DR3, and may not overlap in the second direction DR2.

The cell structure 102 may include a plurality of word lines WL stacked in the third direction DR3. An interlayer insulating layer 130 may be positioned between a plurality of word lines WL. The plurality of word lines WL may be insulated by the interlayer insulating layer 130. The plurality of word lines WL may have a longer length along the second direction DR2 as they get closer to the upper surface of the first substrate 110. The plurality of word lines WL may have a staircase structure with a step along the second direction DR2. On the upper surface of one end of each of the plurality of word lines WL along the second direction DR2, a cell contact via CV connecting the word line WL and the first wiring layer 180 may be positioned. Other word lines WL may not be positioned between the upper surface of one end of each of the plurality of word line WL along the second direction DR2 and the lower surface of the first wiring layer 180.

The word line WL may include a conductive material. The word line WL may include, for example, a doped semiconductor material, a conductive metal nitride, a metal, a metal-semiconductor compound, or a combination thereof, but the embodiments are not limited thereto. In one or more examples, the word line WL and the bit line BL may be the same shape. In one or more examples, the word line WL and the bit line BL may be different shapes.

The cell structure 102 may include a cell gate insulation layer Gox positioned between the cell semiconductor pattern SP and the word line WL. In one or more embodiments, the cell gate insulation layer Gox may surround the channel region 143 of the cell semiconductor pattern SP. The cell gate insulation layer Gox may cover the faces of the cell semiconductor pattern SP facing in the second direction DR2 and the faces facing in the third direction DR3.

The cell gate insulation layer Gox may include at least one of a high dielectric constant material, silicon oxide, silicon nitride, or silicon oxynitride. The high dielectric constant material may include, for example, at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The capacitor CP may include a first capacitor electrode 171, a dielectric layer 173 positioned on the first capacitor electrode 171, a second capacitor electrode 175 positioned on the dielectric layer 173, and a plate electrode 177 positioned on the second capacitor electrode 175. The first capacitor electrode 171 may be in contact with the other end of the cell semiconductor pattern SP along the first direction DR1. The first capacitor electrode 171 may be in contact with the second doping region 142 of the cell semiconductor pattern SP. The semiconductor device according to one or more embodiments may include the plurality of first capacitor electrodes 171. The plurality of first capacitor electrodes 171 may each be in contact with the other end of the plurality of cell semiconductor patterns SP along the first direction DR1. The plurality of first capacitor electrodes 171 may be stacked in the third direction DR3 and spaced apart and arranged along the second direction DR2. The plurality of first capacitor electrodes 171 may be arranged spaced apart along the first direction DR1, and the bit line BL and two cell semiconductor patterns SP each in contact with both sides of the bit line BL may be positioned between the plurality of first capacitor electrodes 171 spaced apart along the first direction DR1.

The dielectric layer 173 may surround the first capacitor electrode 171. In one or more embodiments, the dielectric layer 173 may conformally cover the surfaces of the first capacitor electrode 171 except for the surface in contact with the cell semiconductor pattern SP. For example, the dielectric layer 173 may cover the opposite surface of the surface of the first capacitor electrode 171 that is in contact with the cell semiconductor pattern SP, and the upper surface and the lower surface of the first capacitor electrode 171. The dielectric layer 173 may cover the plurality of first capacitor electrodes 171 that are stacked in the third direction DR3. The dielectric layer 173 may cover the plurality of first capacitor electrodes 171 that are spaced apart in the second direction DR2. The dielectric layer 173 may cover the side surface of the interlayer insulating layer 130 positioned between the plurality of first capacitor electrodes 171. The dielectric layer 173 may cover a portion of the upper surface of the lower insulation layer 120. The dielectric layer 173 may be positioned between the first capacitor electrode 171 and the second capacitor electrode 175. The dielectric layer 173 may connect the plurality of first capacitor electrodes 171 spaced apart along the third direction DR3 and the second direction DR2.

The second capacitor electrode 175 may surround the dielectric layer 173. The second capacitor electrode 175 may cover the dielectric layer 173. The second capacitor electrode 175 may conformally cover the dielectric layer 173. The second capacitor electrode 175 may have a similar shape to the dielectric layer 173. The second capacitor electrode 175 may entirely cover the plurality of first capacitor electrodes 171 spaced apart along the third direction DR3 and the second direction DR2. The plurality of first capacitor electrodes 171 and the opposing second capacitor electrodes 175 may be connected to each other. For example, within one cell structure 102, the plurality of first capacitor electrodes 171 may be covered by the single second capacitor electrode 175.

The plate electrode 177 may surround the second capacitor electrode 175. The plate electrode 177 may cover the second capacitor electrode 175. The plate electrode 177 may include a vertical part extending in the third direction DR3 and horizontal parts extending from the vertical part in the first direction DR1. The vertical part of the plate electrode 177 may be further extended in the second direction DR2. The vertical part of the plate electrode 177 may have a wall shape extending along the second direction DR2 and the third direction DR3. Some of the horizontal parts of the plate electrode 177 may be positioned between the plurality of first capacitor electrodes 171 stacked along the third direction DR3. Some of the horizontal parts of the plate electrode 177 may be positioned between the lowermost first capacitor electrode 171 among the plurality of first capacitor electrodes 171 and the lower insulation layer 120. Some of the horizontal parts of the plate electrode 177 may be positioned between the uppermost first capacitor electrode 171 among the plurality of first capacitor electrodes 171 and the interlayer insulating layer 130. The plate electrode 177 may entirely cover the plurality of first capacitor electrodes 171 spaced apart along the third direction DR3 and the second direction DR2. The plurality of first capacitor electrodes 171 and the opposing plate electrodes 177 may be connected to each other. For example, within one cell structure 102, the plurality of first capacitor electrodes 171 may be covered by the single plate electrode 177.

Each of the first capacitor electrode 171, the second capacitor electrode 175, and the plate electrode 177 may include a conductive material. Each of the first capacitor electrode 171, the second capacitor electrode 175, and the plate electrode 177 may include at least one of a metallic material, a conductive metal nitride, and a doped semiconductor material. In one or more embodiments, the first capacitor electrode 171 and the second capacitor electrode 175 may include the same material, and the plate electrode 177 may include a different material than the first capacitor electrode 171 and the second capacitor electrode 175. For example, the first capacitor electrode 171 and the second capacitor electrode 175 may include titanium nitride, and the plate electrode 177 may include doped silicon germanium.

The dielectric layer 173 may include at least one of a dielectric material, a ferromagnetic material, or a semi-ferromagnetic material. The dielectric material may include a high dielectric constant material (high-k) material. For example, the dielectric material may include hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or a combination thereof.

The cell structure 102 may include a plurality of memory cells MC. In one or more embodiments, each of the plurality of memory cells MC may include a cell semiconductor pattern SP, a bit line BL in contact with one end of the cell semiconductor pattern SP, a capacitor CP in contact with the other end of the cell semiconductor pattern SP, and a word line WL adjacent to a channel region 143 between the one end and the other end of the cell semiconductor pattern SP. The plurality of memory cells MC of the semiconductor device according to one or more embodiments may each be a DRAM cell including one transistor and one capacitor connected to the transistor. The semiconductor device according to one or more embodiments may be a vertical-stacked DRAM in which the plurality of memory cells MC are stacked in the vertical direction on the upper surface of the first substrate 110. However, the embodiment is not limited to this, and each of the plurality of memory cells MC may be changed into various memory cells such as a SRAM.

The semiconductor device according to one or more embodiments may include a first wiring layer 180 positioned over the cell structure 102 and the diode structure 104. The first wiring layer 180 may be positioned between the cell structure 102 and the core circuit structure 202, and between the diode structure 104 and the peripheral circuit structure 204. The first wiring layer 180 may electrically connect the cell structure 102 and the core circuit structure 202, and electrically connect the diode structure 104 and the peripheral circuit structure 204. The first wiring layer 180 may include a first insulation layer 182, a plurality of first wirings 184, and a plurality of first vias 186.

The first insulation layer 182 may be positioned on the upper surface of the bit line BL, the capacitor CP, and the interlayer insulating layer 130. The first insulation layer 182 may be positioned between the plurality of first wirings 184 and the plurality of first vias 186. The plurality of first wirings 184 and the plurality of first vias 186 may be insulated by the first insulation layer 182. The first wiring layer 180 may be composed of a plurality of layers. The plurality of first wirings 184 may be positioned in the plurality of layers. The plurality of first wirings 184 positioned in the different layers may be connected by a plurality of first vias 186. The plurality of first wirings 184 may connect the plurality of memory cells MC to a core circuit. The plurality of first vias 186 may penetrate the first insulation layer 182 and connect the plurality of first wirings 184 positioned in the different layers. The plurality of first vias 186 may include vias connecting the bit line BL and the plurality of first wirings 184 and vias connecting the capacitor CP and the plurality of first wirings 184.

The first wiring layer 180 may further include a cell contact via CV connecting the word line WL and the first wiring 184. The cell contact via CV may connect the upper surface of one end of the word line WL along the second direction DR2and the lower surface of the first wiring 184 by penetrating the first insulation layer 182 and the interlayer insulating layer 130. The first wiring layer 180 may include a plurality of cell contact vias CV. The plurality of cell contacts via CV may each connect the plurality of word lines WL to the plurality of first wirings 184. The plurality of cell contacts via CV may each connect the plurality of word lines WL to the plurality of first wirings 184.

The first wiring layer 180 may electrically connect the cell structure 102 and the core circuit structure 202. The first wiring layer 180 may electrically connect the plurality of memory cells MC included in the cell structure 102 to the core circuit element CTR included in the core circuit structure 202.

The upper insulation layer 190 may be positioned above the first wiring layer 180, but the embodiments are not limited thereto. In one or more examples, the upper insulation layer 190 may be omitted. The upper insulation layer 190 may be positioned between the first wiring layer 180 and the second substrate 210. In one or more embodiments, the upper insulation layer 190 may include the same material as the interlayer insulating layer 130. In this case, the interface between the interlayer insulating layer 130 and the upper insulation layer 190 may not be recognized. For example, the upper insulation layer 190 may include silicon oxide, silicon nitride, or silicon oxynitride, or a combination thereof, but the embodiments are not limited thereto.

The core circuit structure 202 may include a second substrate 210 and a core circuit element CTR positioned on the second substrate 210. In one or more embodiments, the core circuit element CTR may be various circuit elements constituting the core circuit.

The core circuit may include circuits that write or read a data to the memory cell MC. For example, the core circuit may include a sub-word line driver, a sense amplifier, etc. For example, the core circuit element CTR may be a transistor, but the embodiments are not limited thereto.

The second substrate 210 may include a semiconductor material. For example, the second substrate 210 may include a Group IV semiconductor, a Group III-V compound semiconductor, a Group II-VI compound semiconductor, etc. For example, the second substrate 210 may include a semiconductor such as Si, Ge, or a compound semiconductor such as SiGe, SiC, GaAs, InAs, or InP. For example, the second substrate 210 may be a monocrystalline epitaxial layer grown on a monocrystalline silicon substrate. However, the material of the second substrate 210 is not limited to this and may be changed in various ways.

An element isolation pattern 212 and 214 may be positioned inside the second substrate 210. The element isolation pattern 212 and 214 may be formed by filling an insulating material into a trench having a predetermined depth from the upper surface of the second substrate 210. The element isolation pattern 212 and 214 may include, for example, silicon oxide, but the embodiments are not limited thereto. The insulating material included in the element isolation pattern 212 and 214 may vary widely.

The element isolation pattern 212 and 214 may include a first element isolation pattern 212 and a second element isolation pattern 214. The first element isolation pattern 212 may have a shallower depth from the upper surface of the second substrate 210 than the second element isolation pattern 214. The lower surface of the first element isolation pattern 212 may be positioned at a higher level than the lower surface of the second substrate 210. The second element isolation pattern 214 may have a shape that penetrates the second substrate 210. The second element isolation pattern 214 may be formed by filling an insulating material in a trench that is deeper than the first element isolation pattern 212 and performing a wafer thin film forming process until the lower surface of the second element isolation pattern 214 is exposed. The lower surface of the second element isolation pattern 214 may be positioned at the same level as the lower surface of the second substrate 210. The height of the second element isolation pattern 214 along the third direction DR3 may be the same as the thickness of the second substrate 210 along the third direction DR3. Although FIG. 3 illustrates isolation patterns 212 and 214 having different configurations, the embodiments are not limited to this configuration. For example, the isolation patterns 212 and 214 may have the same shape.

The active region of the second substrate 210 may be defined by the element isolation pattern 212 and 214. The plurality of element isolation patterns 212 and 214 may be arranged in a parallel direction on the upper surface of the second substrate 210. The regions of the second substrate 210 between the plurality of element isolation patterns 212 and 214 may be defined as the active region. The core circuit element CTR may be formed in the active region of the second substrate 210. The through via 288 and the second substrate 210 may be isolated by the second element isolation pattern 214.

The core circuit structure 202 may include a plurality of core circuit elements CTR. The semiconductor device according to one or more embodiments may include a second wiring layer 280 positioned over the core circuit structure 202 and the peripheral circuit structure 204. The second wiring layer 280 may interconnect the plurality of core circuit elements CTR or connect the plurality of core circuit elements CTR to an external circuit. The second wiring layer 280 may include a second insulation layer 282, a plurality of second wirings 284, and a plurality of second vias 286.

The second insulation layer 282 may be positioned on the second substrate 210 and the plurality of core circuit elements CTR. The second insulation layer 282 may be positioned between the plurality of second wirings 284 and the plurality of second vias 286. The plurality of second wirings 284 and the plurality of second vias 286 may be isolated by the second insulation layer 282. The second wiring layer 280 may be formed of a plurality of layers. The plurality of second wirings 284 may be positioned in the plurality of layers. The plurality of second wirings 284 positioned in the different layers may be connected by a plurality of second vias 286. The plurality of second vias 286 may connect the plurality of second wirings 284 positioned in the different layers by penetrating the second insulation layer 282. The plurality of second vias 286 may include vias connecting the core circuit element CTR and the plurality of second wirings 284. For example, if the core circuit element CTR is a transistor, the plurality of second vias 286 may include vias connecting the source regions, the drain region, and the gate electrode of the transistor, respectively, to the plurality of second wirings 284.

The second wiring layer 280 may further include a through via 288 connecting the second wiring 284 and the first wiring 184. The through via 288 may penetrate the second insulation layer 282, the second element isolation pattern 214, the upper insulation layer 190, and the first insulation layer 182 to connect the upper surface of the first wiring 184 and the lower surface of the second wiring 284. The second wiring layer 280 may include a plurality of through vias 288. For example, some of the plurality of through via 288 may connect a first wiring 184 connected to the capacitor CP and a second wiring 284 connected to the core circuit element CTR for applying a voltage to the capacitor CP. Another part of the plurality of through vias 288 may connect the first wiring 184 connected to the bit line BL and the second wiring 284 connected to the core circuit element CTR for sensing the voltage of the bit line BL. Another part of the plurality of through via 288 may connect the first wiring 184 connected to the word line WL and the second wiring 284 connected to the core circuit element CTR for applying the voltage to the word line WL.

Next, the diode structure 104 and the peripheral circuit structure 204 are described with reference to FIG. 5 to FIG. 7. In one or more embodiments, at least a portion of the diode structure 104 may be formed in the same process as a portion of the cell structure 102 described above. Accordingly, at least a portion of the diode structure 104 may have a structure identical or similar to a portion of the cell structure 102.

Referring to FIG. 5 to FIG. 7, the diode structure 104 may include plurality of diode semiconductor patterns DSP stacked on the first substrate 110, a first electrode 151 in contact with one end of each of the plurality of diode semiconductor patterns DSP along the first direction DR1 and extending in a vertical direction to the upper surface of the first substrate 110, a second electrode 152 in contact with the other end of each of the plurality of diode semiconductor patterns DSP along the first direction DR1 and extending in a vertical direction to the upper surface of the first substrate 110, and a diode gate electrode DGE adjacent to the diode semiconductor pattern DSP and extending to a second direction DR2 intersecting the first direction DR1.

The diode structure 104 may include a lower insulation layer 122 positioned over the first substrate 110. In one or more examples, the lower insulation layer 122 of the diode structure 104 may be formed by the same process as the lower insulation layer (120 of FIG. 3 and FIG. 4) of the cell structure (102 of FIG. 1 and FIG. 2). The lower insulation layer 122 of the diode structure 104 may be integrally formed with the lower insulation layer 120 of the cell structure 102. The lower insulation layer 122 of the diode structure 104 may include the same material as the lower insulation layer 120 of the cell structure 102. The lower insulation layer 122 of the diode structure 104 may include, for example, silicon oxide, silicon nitride, or silicon oxynitride, or a combination thereof.

The plurality of diode semiconductor patterns DSP may be stacked on the lower insulation layer 122. The plurality of diode semiconductor patterns DSP may be arranged spaced apart in the third direction DR3 on the lower insulation layer 122. The plurality of diode semiconductor patterns DSP spaced apart and arranged in the third direction DR3 may be connected by the first electrode 151 and the second electrode 152. The plurality of diode semiconductor patterns DSP may be placed in the same layer to be spaced apart in the second direction DR2. In one or more embodiments, the plurality of diode semiconductor patterns DSP spaced apart and arranged in the second direction DR2 may be surrounded by one diode gate electrode DGE. According to the embodiment, two diode gate electrodes DGE spaced apart and arranged in the third direction DR3 may be displaced above and below the plurality of diode semiconductor patterns DSP spaced apart and arranged in the second direction DR2. In one or more examples, each of two diode gate electrodes DGE may extend in the second direction DR2 and face each other in the third direction DR3. The plurality of diode semiconductor patterns DSP may be arranged and spaced apart in the second direction DR2 between two diode gate electrodes DGE.

The plurality of diode semiconductor patterns DSP may be formed in the same process as the plurality of cell semiconductor patterns (SP of FIG. 2 to FIG. 4). The diode semiconductor pattern DSP may include the same material as the cell semiconductor pattern SP. The diode semiconductor pattern DSP may include a semiconductor material. For example, the diode semiconductor pattern DSP may include silicon, germanium, or silicon-germanium. For example, the diode semiconductor pattern DSP may include monocrystalline silicon or polycrystalline silicon. Each diode semiconductor pattern DSP may include one or more circuit elements. In one or more examples, each diode semiconductor pattern DSP in the plurality of diode semiconductor patterns may be identical. In one or more examples, at least one diode semiconductor pattern DSP in the plurality of diode semiconductor patterns may have a different shape or different circuit elements than the other diode semiconductor patterns.

The diode semiconductor pattern DSP may have the same shape as the cell semiconductor pattern SP. The diode semiconductor pattern DSP may be extended in the first direction DR1. The diode semiconductor pattern DSP may have a rod or pillar shape. For example, the diode semiconductor pattern DSP may have a square prism shape, but the embodiments are not limited thereto. One end of the diode semiconductor pattern DSP along the first direction DR1 may be in contact with the first electrode 151. The other end of the diode semiconductor pattern DSP along the first direction DR1 may be in contact with the second electrode 152.

The diode semiconductor pattern DSP may include a first doping region 161 in contact with a first electrode 151, a second doping region 162 in contact with a second electrode 152, and an intrinsic region 163 positioned between the first doping region 161 and the second doping region 162. In one or more embodiments, the first doping region 161 and the second doping region 162 may include different types of dopants. For example, the first doping region 161 may include an n type dopant, and the second doping region 162 may include a p type dopant. However, the embodiments are not limited to this configuration. For example, the first doping region 161 may include a p type dopant and the second doping region 162 may include an n type dopant. The intrinsic region 163 may be an intrinsic semiconductor. For example, the intrinsic region 163 may be an undoped or low concentration doped semiconductor. For example, the intrinsic region 163 may include no dopant or a small amount of dopant. In one or more examples, an intrinsic semiconductor may be a pure, undoped semiconductor where the concentration of electrons and holes is equal, and its conductivity is determined solely by its own properties instead of added impurities.

One of the first doping region 161 or the second doping region 162 of the diode semiconductor pattern DSP may be formed in the same process as the first doping region (141 of FIG. 3) or the second doping region (142 of FIG. 3) of the cell semiconductor pattern SP. The other one of the first doping region 161 and the second doping region 162 of the diode semiconductor pattern DSP may be formed in a different process from the first doping region 141 and the second doping region 142 of the cell semiconductor pattern SP. For example, the doping region formed in the same process as the first doping region 141 and the second doping region 163 of the cell semiconductor pattern SP of the first doping region 161 and the second doping region 162 of the diode semiconductor pattern DSP may include the same type of the dopant as the first doping region 141 and the second doping region 163 the cell semiconductor pattern SP.

In one or more embodiments, one end and the other end of the diode semiconductor pattern DSP along the first direction DR1may include different types of dopants. One end of the diode semiconductor pattern DSP along the first direction DR1 may have the same type as both ends of the cell semiconductor pattern SP along the first direction DR1, and the other end of the diode semiconductor pattern DSP along the first direction DR1 may have a different type from both ends of the cell semiconductor pattern SP along the first direction DR1.

The diode structure 104 may include an interlayer insulating layer 132 positioned between the plurality of diode semiconductor patterns DSP spaced apart in the third direction DR3. The interlayer insulating layer 132 of the diode structure 104 may be formed by the same process as the interlayer insulating layer (130 of FIG. 3 and FIG. 4) of the cell structure (102 of FIG. 1 and FIG. 2). The interlayer insulating layer 132 of the diode structure 104 may be integrally formed with the interlayer insulating layer 130 of the cell structure 102. The interlayer insulating layer 132 of the diode structure 104 may include the same material as the interlayer insulating layer 130 of the cell structure 102. The interlayer insulating layer 132 of the diode structure 104 may include, for example, silicon oxide, silicon nitride, or silicon oxynitride, or a combination thereof.

The first electrode 151 and the second electrode 152 may be formed in the same process as the bit line (BL in FIG. 2 and FIG. 3). The first electrode 151 and the second electrode 152 may include the same material as the bit line BL, but the embodiments are not limited thereto. At least one of the first electrode 151 and the second electrode 152 may contain a material different from the bit line BL. The first electrode 151 and the second electrode 152 may include the same material or may include different materials.

The first electrode 151 and the second electrode 152 may include a conductive material. Each of the first electrode 151 and the second electrode 152 may include, for example, a doped semiconductor material, a conductive metal nitride, a metal, a metal-semiconductor compound, or a combination thereof, but the embodiments are not limited thereto.

The first electrode 151 and the second electrode 152 may have the same shape as the bit line BL. Each of the first electrode 151 and the second electrode 152 may be extended in the third direction DR3 on the first substrate 110. Each of the first electrode 151 and the second electrode 152 may have a column shape. For example, each of the first electrode 151 and the second electrode 152 may have a column shape, but the embodiments are not limited thereto.

The lower insulation layer 122 may be positioned between the first electrode 151 and the second electrode 152, and the first substrate 110. The first electrode 151 and the second electrode 152 may be insulated from the first substrate 110 by the lower insulation layer 122.

In one or more embodiments, the first electrode 151 may be in contact with one end of the diode semiconductor pattern DSP along the first direction DR1. The first electrode 151 may be in contact with the first doping region 161 of the diode semiconductor pattern DSP. The plurality of diode semiconductor patterns stacked in the third direction DR3 DSP may be connected to the same first electrode 151. The first electrode 151 may be referred to as a cathode electrode or an anode electrode depending on the doping type of the first doping region 161. For example, if the first doping region 161 is the p-type, the first electrode 151 in contact with the first doping region 161 may be an anode. For example, if the first doping region 161 is the n-type, the first electrode 151 in contact with the first doping region 161 may be a cathode.

In one or more embodiments, the second electrode 152 may be in contact with the other end of the diode semiconductor pattern DSP along the first direction DR1. The second electrode 152 may be in contact with the second doping region 162 of the diode semiconductor pattern DSP. The plurality of diode semiconductor patterns stacked in the third direction DR3 DSP may be connected to the same second electrode 152. The second electrode 152 may be referred to as a cathode or an anode depending on the doping type of the second doping region 162. For example, if the second doping region 162 is the p-type, the second electrode 152 in contact with the second doping region 162 may be an anode. For example, if the second doping region 162 is the n-type, the second electrode 152 in contact with the second doping region 162 may be a cathode.

The diode structure 104 may include a plurality of first electrodes 151 and a plurality of second electrodes 152. The plurality of first electrodes 151 may be spaced and positioned along the second direction DR2. The plurality of second electrodes 152 may be spaced and positioned along the second direction DR2. In one or more embodiments, the plurality of diode semiconductor patterns DSP spaced apart and arranged in the second direction DR2 may each be in contact with the plurality of first electrodes 151 spaced apart and arranged in the second direction DR2. The plurality of diode semiconductor patterns DSP spaced apart and arranged in the second direction DR2 may be each come into contact with the plurality of second electrodes 152 spaced apart and arranged in the second direction DR2.

The diode gate electrode DGE may be formed in the same process as the word line (WL in FIG. 2 to FIG. 4). The diode gate electrode DGE may include the same material as the word line WL. The diode gate electrode DGE may include a conductive material. The diode gate electrode DGE may include, for example, a doped semiconductor material, conductive metal nitride, metal, metal-semiconductor compound, or a combination thereof, but the embodiments are not limited thereto.

The diode gate electrode DGE may have the same shape as the word line WL. The diode gate electrode DGE may extend in a direction crossing the diode semiconductor pattern DSP. The diode gate electrode DGE may extend in the second direction DR2. The diode gate electrode DGE may cover the plurality of diode semiconductor patterns DSP spaced apart and placed in the second direction DR2. In one or more embodiments, the diode gate electrode DGE may surround the plurality of diode semiconductor patterns DSP spaced apart and arranged in the second direction DR2. In one or more examples, the diode gate electrode DGE may overlap the plurality of diode semiconductor patterns DSP spaced apart in the second direction DR2 in the second direction DR2 and third direction DR3. According to the embodiment, the diode gate electrode DGE may cover one surface of the plurality of diode semiconductor patterns DSP spaced apart in the second direction DR2 along the third direction DR3. In one or more examples, the diode gate electrode DGE may overlap the plurality of diode semiconductor patterns DSP spaced apart in the second direction DR2 in the third direction DR3, and may not overlap them in the second direction DR2.

The diode gate electrode DGE may be positioned on both sides of the diode semiconductor pattern DSP. In one or more embodiments, the diode gate electrode DGE may be positioned on both sides of the diode semiconductor pattern DSP along the third direction DR3 and on both sides of the diode semiconductor pattern DSP along the second direction DR2. The diode gate electrode DGE may be positioned on the upper surface, the lower surface of the diode semiconductor pattern DSP, and both sides along the second direction DR2. The diode gate electrode DGE may surround the intrinsic region 163 of the diode semiconductor pattern DSP.

The intrinsic region 163 of the diode semiconductor pattern DSP may be a region that overlaps the diode gate electrode DGE. In one or more embodiments, the intrinsic region 163 may overlap the diode gate electrode DGE in the third direction DR3 and the second direction DR2. The faces facing of the intrinsic region 163 in the third direction DR3 and the faces facing in the second direction DR2 may be surrounded by the diode gate electrode DGE. In one or more embodiments, the entire surface of the intrinsic region 163 of the diode semiconductor pattern DSP may be surrounded by the diode gate electrode DGE. However, the embodiment is not limited thereto. The semiconductor device according to one or more embodiments may include two diode gate electrodes DGE each covering the faces facing of the intrinsic region 163 in the third direction DR3, according to the structure of the word line WL of the cell structure 102. In one or more examples, the two diode gate electrodes DGE may overlap the intrinsic region 163 in the third direction DR3, and may not overlap it in the second direction DR2.

The diode structure 104 may include a plurality of diode gate electrodes DGE stacked in the third direction DR3. An interlayer insulating layer 132 may be positioned between the plurality of diode gate electrodes DGE. The plurality of diode gate electrodes DGE may be insulated by the interlayer insulating layer 132. In one or more embodiments, the plurality of diode gate electrodes DGE may have a longer length along the second direction DR2 closer to the upper surface of the first substrate 110. The plurality of diode gate electrodes DGE may have a stepped structure along the second direction DR2. A diode contact via DCV may be positioned on the upper surface of one end of each of the plurality of diode gate electrodes DGE along the second direction DR2 to connect the diode gate electrode DGE and the first wiring layer 180. Other diode gate electrodes DGE may not be positioned between the upper surface of one end of each of the plurality of diode gate electrodes DGE along the second direction DR2 and the lower surface of the first wiring layer 180.

The diode gate insulation layer DGox may be formed in the same process as the gate insulation layer (Gox in FIG. 2 to FIG. 4). The diode gate insulation layer DGox may include the same material as the cell gate insulation layer Gox. The diode gate insulation layer DGox may include at least one of a high dielectric constant material, silicon oxide, silicon nitride, or silicon oxynitride. The high dielectric constant material may include at least one of, for example, hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The diode gate insulation layer DGox may have the same shape as the cell gate insulation layer Gox. The diode gate insulation layer DGox may be positioned between the diode semiconductor pattern DSP and the diode gate electrode DGE. In one or more embodiments, the diode gate insulation layer DGox may surround the intrinsic region 163 of the diode semiconductor pattern DSP. The diode gate insulation layer DGox may cover the faces facing of the diode semiconductor pattern DSP in the third direction DR3 and the faces facing thereof in the second direction DR2.

In one or more embodiments, the diode structure 104 may include a plurality of diodes GD stacked on the first substrate 110. Each of the plurality of diodes GD may include a diode semiconductor pattern DSP, a first electrode 151, and a second electrode 152, and a diode gate electrode DGE. The plurality of diodes GD of the semiconductor device according to one or more embodiments may each be a gated diode including a gate. For example, each of the plurality of diodes GD may be a p-i-n diode or an n-i-p diode.

In one or more embodiments, the diode GD may be a static electricity discharge prevention diode. The diode GD may be formed by forming at least some diodes among several elements that constitute a static electricity discharge prevention circuit together with the memory cell MC on the first substrate 110. In one or more embodiments, the plurality of diodes GD of the diode structure 104 may be connected to the static electricity discharge prevention circuit of the peripheral circuit structure 204. The plurality of diodes GD of the diode structure 104 may be connected to other elements constituting the static electricity discharge prevention circuit of the peripheral circuit structure 204. However, the embodiment is not limited thereto. In addition to the static electricity discharge prevention circuit, the diode GD may be formed by forming diodes among several elements that constitute various peripheral circuits, such as an address decoder, refresh circuit, input/output buffer, and power management circuit along with the memory cell MC on the first substrate 110. The semiconductor device according to one or more embodiments may be formed together in a process of forming the plurality of memory cells MC in which some diodes constituting the peripheral circuit are stacked in a direction vertical to the upper surface of the first substrate 110. The semiconductor device according to one or more embodiments may include a diode structure 104 formed on the same substrate as the cell structure 102 in which the plurality of memory cells MC are stacked and having the structure similar to the cell structure 102. The diode structure 104 may have a structure in which the plurality of diodes GD are stacked in a vertical direction the the upper surface of the first substrate 110, which is the same as the cell structure 102. In general, a diode may operate without a gate, but since the diode structure 104 according to one or more embodiments is formed together with some process of forming the cell structure 102, it may include the diode gate electrode DGE having the shape and structure identical or similar to the word line WL of the cell structure 102.

In one or more embodiments, the first wiring layer 180 may be positioned on the diode structure 104. The first wiring layer 180 may be positioned between the diode structure 104 and the second substrate 210. The first wiring layer 180 may include a first insulation layer 182, a plurality of first wirings 184, and a plurality of first vias 186.

In one or more embodiments, the first insulation layer 182 may be positioned on the upper surfaces of the first electrode 151, the second electrode 152, and the interlayer insulating layer 132. The plurality of first wirings 184 may connect the plurality of diodes GD to the peripheral circuit. The plurality of first vias 186 may include a via connecting the first electrode 151 and the plurality of first wirings 184 and a via connecting the second electrode 152 and the plurality of first wirings 184.

In one or more embodiments, the first wiring layer 180 may further include a diode contact via DCV connecting the diode gate electrode DGE and the first wiring 184. The diode contact via DCV may connect the upper surface of one end of the diode gate electrode DGE along the second direction DR2 and the lower surface of the first wiring 184 by penetrating the first insulation layer 182 and the interlayer insulating layer 132. The first wiring layer 180 may include a plurality of diode contact vias DCV. In one or more embodiments, the plurality of diode contact vias DCV may each connect the plurality of diode gate electrodes DGE to the same first wiring 184. Each diode gate electrode DGE of the plurality of diodes GD may be connected to each other by the same first wiring 184. For example, the same voltage may be applied to each diode gate electrode DGE of the plurality of diodes GD.

The first wiring layer 180 may electrically connect the diode structure 104 and the peripheral circuit structure 204. The first wiring layer 180 may electrically connect the plurality of memory cells MC included in the diode structure 104 to the peripheral circuit element PTR included in the peripheral circuit structure 204.

The upper insulation layer 190 may be positioned above the first wiring layer 180, but the embodiments are not limited thereto. In one or more embodiments, the upper insulation layer 190 may include the same material as the interlayer insulating layer 132. In this case, the interface between the interlayer insulating layer 132 and the upper insulation layer 190 may not be recognized.

The peripheral circuit structure 204 may include a second substrate 210 and a peripheral circuit element PTR positioned on the second substrate 210. In one or more embodiments, the peripheral circuit element PTR may be any of various circuit elements constituting the peripheral circuit. The peripheral circuit may include control circuits for driving the semiconductor device. For example, the peripheral circuit may include an address decoder, a refresh circuit, an input/output buffer, a power management circuit, etc. For example, the peripheral circuit element PTR may be a transistor, but the embodiments are not limited thereto.

An element isolation pattern 212 and 214 may be positioned inside the second substrate 210. The active region of the second substrate 210 may be defined by the element isolation pattern 212 and 214. A region of the second substrate 210 between the plurality of element isolation patterns 212 and 214 may be defined as an active region. The second substrate 210 may include a plurality of active regions. The core circuit elements CTR may be formed in some of the plurality of active regions of the second substrate 210 and the peripheral circuit elements PTR may be formed in others. The core circuit element CTR and the peripheral circuit element PTR may be arranged spaced apart in a parallel direction on the upper surface of the second substrate 210. In one or more embodiments, the core circuit element CTR may overlap the cell structure 102 in the third direction DR3, and the peripheral circuit element PTR may overlap the diode structure 104 in the third direction DR3.

The peripheral circuit structure 204 may include a plurality of peripheral circuit elements PTR. In one or more embodiments, the second wiring layer 280 may be positioned above the peripheral circuit structure 204. The second wiring layer 280 may be positioned on the plurality of peripheral circuit elements PTR. The second wiring layer 280 may include a second insulation layer 282, a plurality of second wirings 284, and a plurality of second vias 286.

In one or more embodiments, the second insulation layer 282 may be positioned over the second substrate 210 and the plurality of peripheral circuit elements PTR. The plurality of second wirings 284 may interconnect the plurality of peripheral circuit elements PTR, or may connect the plurality of peripheral circuit elements PTR to an external circuit. The plurality of second vias 286 may include vias connecting the peripheral circuit element PTR and the plurality of second wirings 284. For example, if the peripheral circuit element PTR is a transistor, the plurality of second vias 286 may include vias connecting the source region, the drain region, and the gate electrode of the transistor, respectively, to the plurality of second wirings 284.

In one or more embodiments, the second wiring layer 280 may be connected to the first wiring layer 180 by a plurality of through vias 288. For example, some of the plurality of through vias 288 may connect the first wiring 184 connected to the first electrode 151 and the second wiring 284 connected to the peripheral circuit element PTR for applying a voltage to the first electrode 151. Another part of the plurality of through via 288 may connect the first wiring 184 connected to the second electrode 152 and the second wiring 284 connected to the peripheral circuit element PTR for applying a voltage to the second electrode 152. Another part of the plurality of through via 288 may connect the first wiring 184 connected to the diode gate electrode DGE and the second wiring 284 connected to the peripheral circuit element PTR for applying a voltage to the diode gate electrode DGE.

The semiconductor device according to one or more embodiments may include a cell structure 102 and a diode structure 104 arranged on the first substrate 110 in a direction parallel to the upper surface of the first substrate 110. In one or more embodiments, the diode structure 104 may have a structure similar to the cell structure 102, as it is formed together in some process forming the cell structure 102. In one or more embodiments, the diode structure 104 may include a plurality of diode semiconductor patterns DSP formed together with the plurality of cell semiconductor patterns SP of the cell structure 102. The plurality of diode semiconductor patterns DSP may be stacked on the first substrate 110. In one or more embodiments, unlike the cell semiconductor pattern SP, one end and the other end of the diode semiconductor pattern DSP along the first direction DR1 may include different types of dopants. In one or more embodiments, the diode structure 104 may include the first electrode 151 and the second electrode 152 formed together with the bit line BL of the cell structure 102. The first electrode 151 may be in contact with one end of each of the plurality of diode semiconductor patterns DSP stacked on the first substrate 110 along the first direction DR1, and may extend in the third direction DR3 perpendicular to the upper surface of the first substrate 110. The second electrode 152 may be in contact with the other end of each of the plurality of diode semiconductor patterns DSP stacked on the first substrate 110 along the first direction DR1 and may extend in the third direction DR3. In one or more embodiments, the diode structure 104 may include the diode gate electrode DGE formed together with the word line WL of the cell structure 102. The diode gate electrode DGE may be adjacent to the diode semiconductor pattern DSP and be extended to the second direction DR2, which intersects the first direction DR1. In one or more embodiments, the diode structure 104 may include a diode GD including the diode semiconductor pattern DSP, the first electrode 151, the second electrode 152, and the diode gate electrode DGE. In one or more embodiments, the diode structure 104 may have a structure in which the plurality of diodes GD are stacked in the third direction DR3 perpendicular to the upper surface of the first substrate 110 on the first substrate 110.

The plurality of diodes GD of the semiconductor device according to one or more embodiments may be connected to the peripheral circuit element PTR positioned on the second substrate 210 positioned on the cell structure 102 and the diode structure 104. The semiconductor device according to one or more embodiments may be formed by forming the memory cell and the core/peripheral circuit on the different substrates and then bonding the second substrate 210 on which the core/peripheral circuit is formed on the first substrate 110 on which the memory cell is formed. In one or more examples, a diode such as the static electricity discharge prevention diode may be formed by utilizing a wall region of a different type from the second substrate 210 formed within the second substrate 210. However, since the back surface of the second substrate 210 is ground down to a predetermined thickness in order to bond the second substrate 210 onto the first substrate 110, the thickness of the wall region may be reduced. Accordingly, a width of a conduction path of the diode narrows, and a larger horizontal area of the second substrate 210 may be required to form the diode separately. According to one or more embodiments, by forming some of the diodes that constitute the peripheral circuit together with the memory cell on the first substrate 110 where the memory cell is formed, the area of the second substrate 210 where the peripheral circuit is formed may be reduced, and the size of the semiconductor chip may be reduced.

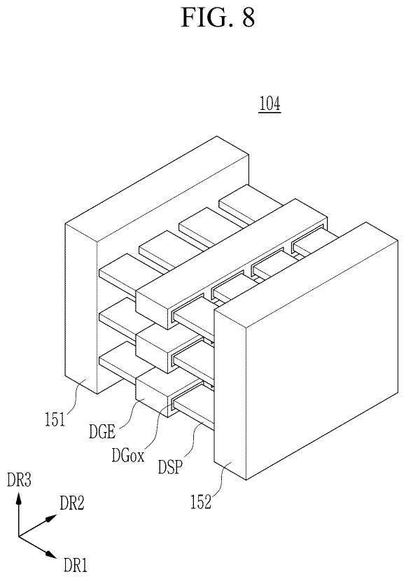

Hereinafter, variations of the semiconductor device according to the embodiments illustrated in FIG. 2 to FIG. 7 are described with reference to FIG. 8.

FIG. 8 is a schematic perspective view of a diode structure of a semiconductor device according to one or more embodiments. The embodiment illustrated in FIG. 8 may be substantially identical to the embodiment illustrated in FIG. 5. In the embodiment illustrated in FIG. 8, the same components as in the embodiment illustrated in FIG. 5 may be referenced by the same symbols. Below, the embodiment illustrated in FIG. 8 will be described with a focus on the differences from the embodiment illustrated in FIG. 5. The embodiment illustrated in FIG. 8 may have slightly different shapes of the first electrode 151 and the second electrode 152 of the diode structure 104 from the embodiment illustrated in FIG. 5.

Referring to FIG. 8, the first electrode 151 of the semiconductor device according to one or more embodiments may be in contact with one end of each of the plurality of diode semiconductor patterns DSP stacked in the third direction DR3 along the first direction DR1 and may extend in the third direction DR3. The second electrode 152 of the semiconductor device according to one or more embodiments may be in contact with the other end of each of the plurality of diode semiconductor patterns DSP stacked in the third direction DR3 along the first direction DR1 and may extend in the third direction DR3. One end of the diode semiconductor pattern DSP in contact with the first electrode 151 and the other end of the diode semiconductor pattern DSP in contact with the second electrode 152 may include dopants of different types.

In the embodiment illustrated in FIG. 8, unlike the embodiment illustrated in FIG. 5, each of the first electrode 151 and the second electrode 152 may be further extended in the second direction DR2. For example, the first electrode 151 and the second electrode 152 may have wall shapes parallel to the second direction DR2 and the third direction DR3. The plurality of diode semiconductor patterns DSP may include the diode semiconductor patterns DSP spaced apart and arranged in the second direction DR2 in the same layer. In one or more embodiments, diode semiconductor patterns DSP arranged and spaced apart in the second direction DR2 may be in contact with the single first electrode 151 and the single second electrode 152. The first electrode 151 is spaced apart in the second direction DR2 and may come into contact with one end of each diode semiconductor patterns DSP along the first direction DR1. The second electrode 152 is spaced apart in the second direction DR2 and may be in contact with the other end of each diode semiconductor patterns DSP along the first direction DR1.

For example, the same voltage may be applied to one end of each of the plurality of diode semiconductor patterns DSP of the diode structure 104 along the first direction DR1. The same voltage may be applied to the other end of each of each of the plurality of diode semiconductor patterns DSP of the diode structure 104 along the first direction DR1.

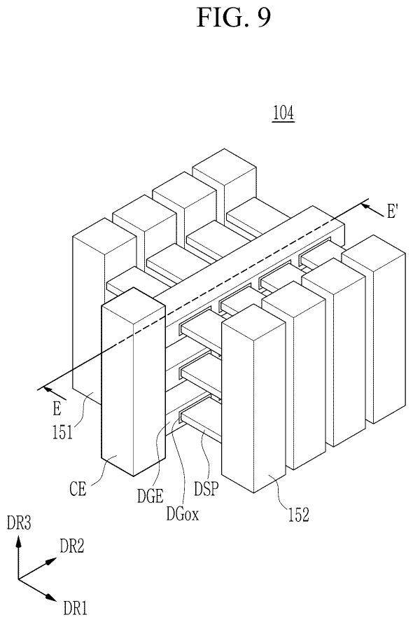

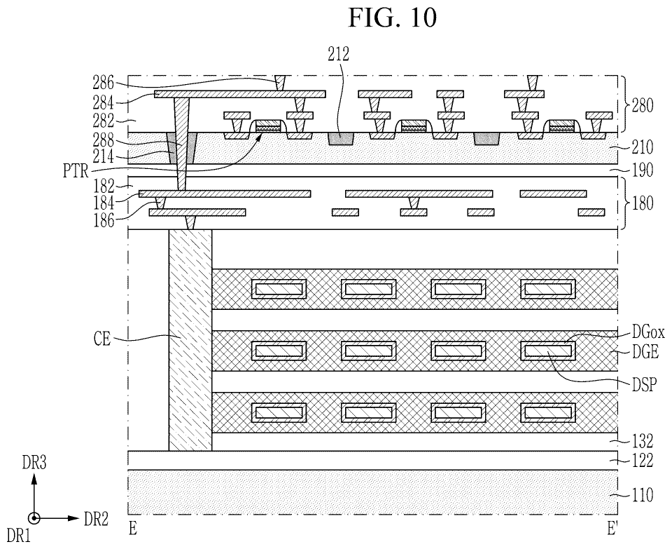

Below, variations of the semiconductor device according to the embodiments illustrated in FIG. 2 to FIG. 7 are described with reference to FIG. 9 and FIG. 10.

FIG. 9 is a schematic perspective view of a diode structure of a semiconductor device according to one or more embodiments. FIG. 10 is a cross-sectional view of a diode structure according to one or more embodiments taken along a line E-E′ of FIG. 9. The embodiments illustrated in FIG. 9 and FIG. 10 may be substantially identical to the embodiments illustrated in FIG. 5 and FIG. 7. In the embodiments illustrated in FIG. 9 and FIG. 10, the same components as in the embodiments illustrated in FIG. 5 and FIG. 7 may be referenced by the same symbols. Below, the differences between the embodiments illustrated in FIG. 9 and FIG. 10 and the embodiments illustrated in FIG. 5 and FIG. 7 will be mainly described. The embodiment illustrated in FIG. 9 and FIG. 10 may have some differences in the connection structure of the diode gate electrode DGE of the diode structure 104 and the first wiring layer 180 from the embodiment illustrated in FIG. 5 and FIG. 7.

Referring to FIG. 9 and FIG. 10, the semiconductor device according to one or more embodiments may include a plurality of diode gate electrodes DGE stacked in the third direction DR3. Each of the plurality of diode gate electrodes DGE stacked in the third direction DR3 may surround each of the plurality of diode semiconductor patterns DSP stacked in the third direction DR3. The plurality of diode gate electrodes DGE each may be extended to the second direction DR2. The diode gate electrode DGE may surround the diode semiconductor patterns DSP, which are spaced apart in the second direction DR2 in the same layer.

In the embodiments illustrated in FIG. 9 and FIG. 10, unlike the embodiments illustrated in FIG. 5 and FIG. 7, the plurality of diode gate electrodes DGE may have the same length along the second direction DR2 regardless of the distance from the upper surface of the first substrate 110. The semiconductor device according to one or more embodiments may include a contact electrode CE in contact with one end of each of the plurality of diode gate electrodes DGE along the second direction DR2. The contact electrode CE may extend in the third direction DR3 vertical to the upper surface of the first substrate 110 through the interlayer insulating layer 132. For example, the contact electrode CE may have a pillar shape, but the embodiments are not limited thereto. A lower insulation layer 122 may be positioned between the contact electrode CE and the first substrate 110. The contact electrode CE may be insulated from the first substrate 110 by the lower insulation layer 122. The contact electrode CE may be electrically connected to the first wiring layer 180. For example, the plurality of first vias 186 may include vias connecting the contact electrode CE and the first wiring 184. In the embodiments shown in FIG. 9 and FIG. 10, the contact electrode CE may replace the role of the diode contact via DCV, which is connected to the upper surface of each of the plurality of diode gate electrodes DGE.

In one or more embodiments, the plurality of diode gate electrodes DCE stacked in the third direction DR3 may be connected by a single contact electrode CE. The plurality of diode gate electrodes DCE may be supplied with the same voltage.

According to one or more embodiments, the width (or the area) occupied by the plurality of diode gate electrodes DGE in the second direction DR2 may be reduced compared to the embodiments shown in FIG. 5 and FIG. 7 in which the plurality of diode gate electrodes DGE have the stepped structure with the steps along the second direction DR2, so that the size of the semiconductor chip may be further reduced.

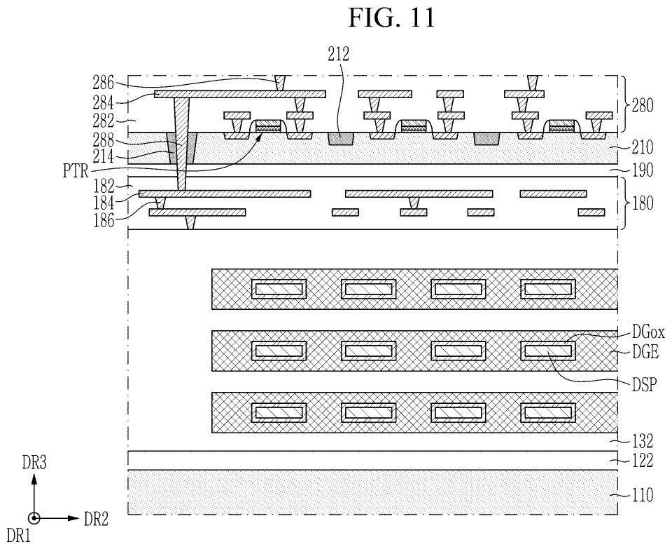

Below, variations of the semiconductor device according to the embodiments illustrated in FIG. 9 and FIG. 10 are described with reference to FIG. 11.

FIG. 11 is a cross-sectional view of a diode structure according to one or more embodiments. The embodiment illustrated in FIG. 11 may be substantially identical to the embodiments illustrated in FIG. 9 and FIG. 10. In the embodiment illustrated in FIG. 11, the same components as in the embodiments illustrated in FIG. 9 and FIG. 10 may be referenced by the same symbols. Below, the embodiment illustrated in FIG. 11 will be described mainly focusing the differences from the embodiments illustrated in FIG. 9 and FIG. 10. The embodiment illustrated in FIG. 11 may differ in some respects from the embodiments illustrated in FIG. 9 and FIG. 10 in that the contact electrode CE connected to the diode gate electrode DGE of the diode structure 104 is omitted.

In the embodiment shown in FIG. 11, unlike the embodiment shown in FIG. 9 and FIG. 10, the contact electrode CE that connects the plurality of diode gate electrodes DGE to the first wiring layer 180 may be omitted. In one or more embodiments, the plurality of diode gate electrodes DGE may be floating. For example, a voltage may not be applied to the plurality of diode gate electrodes DGE. Even if no voltage is applied to the plurality of diode gate electrodes DGE, a current may flow in the plurality of diode semiconductor patterns DSP of the diode structure 104 by the voltage applied to the first electrode 151 and the second electrode 152.

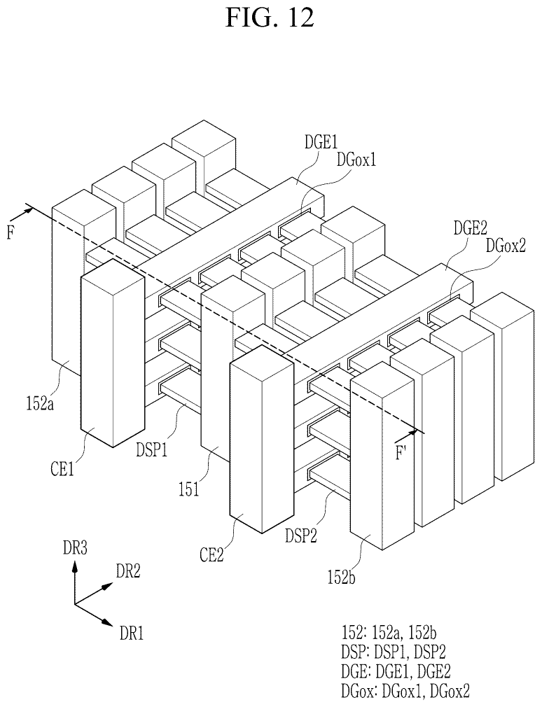

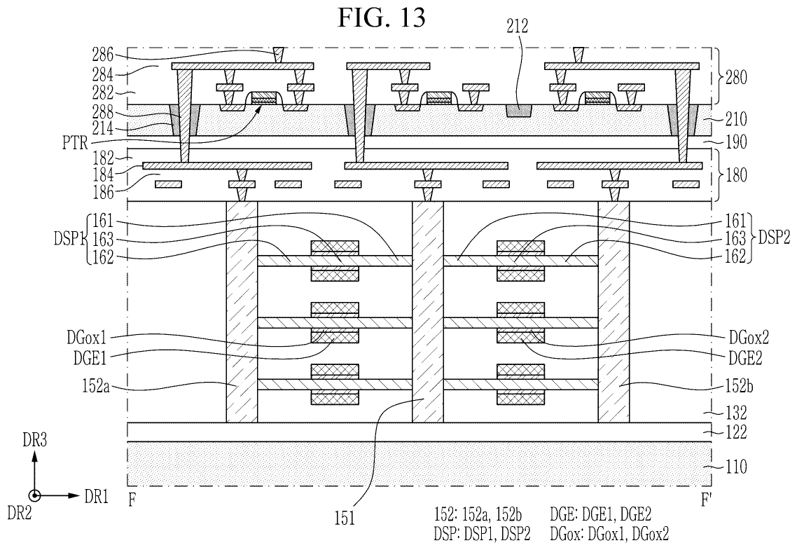

Below, variations of other semiconductor devices are described in the embodiments illustrated in FIG. 9 and FIG. 10 with reference to FIG. 12 and FIG. 13.

FIG. 12 is a schematic perspective view of a diode structure of a semiconductor device according to one or more embodiments. FIG. 13 is a cross-sectional view of a diode structure according to one or more embodiments taken along a line F-F′ of FIG. 12. The embodiments illustrated in FIG. 12 and FIG. 13 may be substantially identical to the embodiments illustrated in FIG. 9 and FIG. 10. In the embodiments illustrated in FIG. 12 and FIG. 13, the same components as in the embodiments illustrated in FIG. 9 and FIG. 10 may be referenced by the same symbols. Below, the differences between the embodiments illustrated in FIG. 12 and FIG. 13 and the embodiments illustrated in FIG. 9 and FIG. 10 will be mainly explained. The embodiments illustrated in FIG. 12 and FIG. 13 may differ in some respects from the embodiments illustrated in FIG. 9 and FIG. 10 in that the diode structure 104 is symmetrical with respect to the first electrode 151 as a reference.

Referring to FIG. 12, one end of each of the plurality of diode semiconductor patterns DSP of the semiconductor device according to one or more embodiments along the first direction DR1 may be in contact with the first electrode 151, and the other end of each of the plurality of diode semiconductor patterns DSP along the first direction DR1 may be in contact with the second electrode 152. One end of the diode semiconductor pattern DSP along the first direction DR1 in contact with the first electrode 151 and the other end of the diode semiconductor pattern DSP along the first direction DR1 in contact with the second electrode 152 may include dopants of different types.

In the embodiments illustrated in FIG. 12 and FIG. 13, unlike the embodiments illustrated in FIG. 9 and FIG. 10, the diode structure 104 may have a symmetrical structure with the first electrode 151 as a reference. In one or more embodiments, the diode structure 104 may include a first diode semiconductor pattern DSP1 in contact with one side of the first electrode 151 along the first direction DR1 and a second diode semiconductor pattern DSP2 in contact with the other side of the first electrode 151 along the first direction DR1. The diode structure 104 may include two second electrodes 152a and 152b spaced apart in the first direction DR1 with the first electrode 151 therebetween.

In one or more embodiments, one side of the first diode semiconductor pattern DSP1 along the first direction DR1 may be in contact with the first electrode 151, and the other side of the first diode semiconductor pattern DSP1 along the first direction DR1 may be in contact with one of two second electrodes 152a. One side of the second diode semiconductor pattern DSP2 along the first direction DR1 may be in contact with the first electrode 151, and the other side of the second diode semiconductor pattern DSP2 along the first direction DR1 may be in contact with the other one of the two second electrodes 152b. For example, one end of each of the first diode semiconductor pattern DSP1 and the second diode semiconductor pattern DSP2 may be in contact with the single first electrode 151, and the other end of each of the first diode semiconductor pattern DSP1 and the second diode semiconductor pattern DSP2 may be in contact with two second electrodes 152a and 152b, respectively.

In one or more embodiments, the end of the first diode semiconductor pattern DSP1 and the end of the second diode semiconductor pattern DSP2 in contact with the first electrode 151 may include a dopant of the same type. The end of the first diode semiconductor pattern DSP1 and the end of the second diode semiconductor pattern DSP2, which are in contact with the two second electrodes 152a and 152b, respectively, may include a dopant of the same type. For example, the end of the first diode semiconductor pattern DSP1 and the end of the second diode semiconductor pattern DSP2 in contact with the first electrode 151 may include a first type dopant. The end of the first diode semiconductor pattern DSP1 and the end of the second diode semiconductor pattern DSP2, which are in contact with the two second electrodes 152a and 152b, respectively, may include a second type dopant. For example, the first type may be an n type and the second type may be a p type. In this case, the first electrode 151 may be a cathode, and two second electrodes 152a and 152b may be an anode. As another example, the first type may be a p type and the second type may be an n type. In this case, the first electrode 151 may be the anode, and two second electrodes 152a and 152b may be the cathodes.

The semiconductor device according to one or more embodiments may include a plurality of diode gate electrodes DGE1 and DGE2 spaced apart in the first direction DR1. In one or more embodiments, the plurality of diode gate electrodes DGE1 and DGE2, which are spaced apart in the first direction DR1, may surround the plurality of diode semiconductor patterns DSP1 and DSP2, which are spaced apart in the first direction DR1, respectively. The semiconductor device according to one or more embodiments may include a plurality of contact electrodes CE1 and CE2 spaced apart in the first direction DR1. The plurality of contact electrodes CE1 and CE2 may each be in contact with one end of the plurality of diode gate electrodes DGE1 and DGE2 spaced apart in the first direction DR1 along the second direction DR2 respectively.

The symmetric structure referring to the first electrode 151 of the embodiment of FIG. 12 and FIG. 13 may be applied to various embodiments regardless of the shape of the plurality of diode gate electrodes DGE and the connection structure of the plurality of diode gate electrodes DGE and the first wiring layer 180. For example, as shown in FIG. 10, the plurality of diode gate electrodes DGE stacked in the third direction DR3 may be floating. As another example, as shown in FIG. 5 to FIG. 7, the length of the plurality of diode gate electrodes DGE stacked in the third direction DR3 along the second direction DR2 may be longer as it approaches the upper surface of the first substrate 110, in this case, each of the plurality of diode gate electrodes DGE stacked in the third direction DR3 may be connected to the first wiring layer 180 by the diode contact via DCV.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor device comprising:
a first substrate;
a cell structure and a diode structure on the first substrate in a first direction parallel to a surface of the first substrate;
a second substrate on the cell structure and the diode structure;
a core circuit element on the second substrate and connected to the cell structure; and
a peripheral circuit element connected to the diode structure,
wherein the cell structure comprises:
a cell semiconductor pattern on the first substrate,
a word line adjacent to the cell semiconductor pattern and extending in a second direction intersecting the first direction, the second direction parallel to the surface of the first substrate
a bit line on one end of the cell semiconductor pattern along the first direction and extending in a third direction perpendicular to the surface of the first substrate, and
a capacitor on another end of the cell semiconductor pattern along the first direction,
wherein the diode structure comprises:
a diode semiconductor pattern on the first substrate,
a first electrode on one end of the diode semiconductor pattern along the first direction and extending in the third direction,
a second electrode on another end of the diode semiconductor pattern along the first direction and extending in the third direction, and
a diode gate electrode adjacent to the diode semiconductor pattern and extending in the second direction.

2. The semiconductor device of claim 1, wherein:
the one end of the diode semiconductor pattern along the first direction includes a first type of dopant, and
another end of the diode semiconductor pattern along the first direction includes a second type of dopant different from the first type of dopant.

3. The semiconductor device of claim 1, wherein:
the core circuit element overlaps the cell structure in the third direction, and
the peripheral circuit element overlaps the diode structure in the third direction.

4. The semiconductor device of claim 1, wherein:
the diode structure comprises a plurality of diode gate electrodes on the first substrate, and
a length of each of the plurality of diode gate electrodes along the second direction varies in accordance with a distance from the surface of the first substrate.

5. The semiconductor device of claim 4, further comprising:
a wiring layer positioned between the diode structure and the second substrate, and
a plurality of diode contact vias, each connected between a surface of each of the plurality of diode gate electrodes and the wiring layer, and
wherein the plurality of diode contact vias and the plurality of diode gate electrodes are connected to a same wiring of the wiring layer.

6. The semiconductor device of claim 1, wherein:
the diode structure comprises a plurality of diode gate electrodes on the first substrate, and
the semiconductor device further comprises a contact electrode on one ends of the plurality of diode gate electrodes along the second direction and extending in the third direction to the surface of the first substrate.

7. The semiconductor device of claim 1, wherein the diode structure further comprises:
a plurality of first electrodes spaced apart in the second direction,
a plurality of second electrodes spaced apart in the second direction, and
a plurality of diode semiconductor patterns spaced apart in the second direction,
wherein each of the plurality of diode semiconductor patterns is on each of the plurality of first electrodes, and
wherein each of the diode semiconductor patterns is on each of the plurality of second electrodes.

8. The semiconductor device of claim 1, wherein the diode structure further comprises a plurality of diode semiconductor patterns spaced apart in the second direction,
wherein:
the first electrode and the second electrode are each further extended in the second direction,
the plurality of diode semiconductor patterns is on a single first electrode, and
the plurality of diode semiconductor patterns is on a single second electrode.

9. The semiconductor device of claim 1, wherein:
the diode structure further comprises a first diode semiconductor pattern on one side of the first electrode along the first direction and a second diode semiconductor pattern on another side of the first electrode along the first direction, and
the diode structure is symmetrical with respect to the first electrode.

10. The semiconductor device of claim 9, wherein:
the diode structure further comprises two second electrodes spaced apart in the first direction with the first electrode interposed therebetween,
a side opposite to a side of the first diode semiconductor pattern on the first electrode is on one of the two second electrodes, and
a side opposite to a side of the second diode semiconductor pattern on the first electrode is on the other one of the two second electrodes.

11. The semiconductor device of claim 10, wherein:
an end of the first diode semiconductor pattern and an end of the second diode semiconductor pattern, which are on the first electrode, include a first type dopant, and
an end of the first diode semiconductor pattern and an end of the second diode semiconductor pattern, which are on the two second electrodes, respectively, include a second type dopant.

12. The semiconductor device of claim 1, wherein:
the diode semiconductor pattern comprises a first doping region on the first electrode, a second doping region on the second electrode, and an intrinsic region between the first doping region and the second doping region and overlapping the diode gate electrode, and
the diode gate electrode surrounds an entire surface of the intrinsic region of the diode semiconductor pattern.

13. The semiconductor device of claim 1, wherein:
the diode structure comprises a diode including the diode semiconductor pattern, the first electrode, the second electrode, and the diode gate electrode, and
the diode is a static electricity discharge prevention diode.

14. The semiconductor device of claim 1, further comprising:
at least two cell structures on the first substrate in the first direction, wherein the diode structure is between the at least two cell structures.

15. A semiconductor device comprising:
a first substrate;
a cell structure and a diode structure on the first substrate in a first direction parallel to a surface of the first substrate;
a second substrate on the cell structure and the diode structure;
a core circuit element on the second substrate and connected to the cell structure; and
a peripheral circuit element connected to the diode structure,
wherein the cell structure comprises:
a memory cell on the first substrate, the memory cell comprising a cell semiconductor pattern, a bit line and a capacitor on the cell semiconductor pattern, and a word line adjacent to the cell semiconductor pattern,
wherein the diode structure comprises:
a diode on the first substrate, the diode comprising a diode semiconductor pattern, a first electrode and a second electrode on the diode semiconductor pattern, and a diode gate electrode adjacent to the diode semiconductor pattern,
wherein a portion of the cell semiconductor pattern on the bit line and a portion of the cell semiconductor pattern on the capacitor include a same type of dopant, and
wherein a portion of the diode semiconductor pattern on the first electrode and a portion of the diode semiconductor pattern on the second electrode include different types of dopant.

16. The semiconductor device of claim 15, wherein:
the bit line, the first electrode, and the second electrode each extend in a second direction perpendicular to the first direction.

17. The semiconductor device of claim 15, wherein:
the word line and the diode gate electrode each intersect the cell semiconductor pattern and the diode semiconductor pattern respectively, and extend in the first direction.

18. A semiconductor device comprising:
a first substrate;
a cell structure and a diode structure on the first substrate in a first direction parallel to a surface of the first substrate;
a second substrate on the cell structure and the diode structure;
a core circuit structure overlapping the cell structure on the second substrate; and
a peripheral circuit structure overlapping the diode structure on the second substrate,
wherein the cell structure comprises:
a memory cell on the first substrate, the memory cell comprising a cell semiconductor pattern,
a bit line on one end of the cell semiconductor pattern along the first direction,
a capacitor on another end of the cell semiconductor pattern along the first direction, and
a word line adjacent to the cell semiconductor pattern and extending in a second direction intersecting the first direction, the second direction parallel to the surface of the first substrate,
wherein the diode structure comprises:
a diode on the first substrate, the diode comprising a diode semiconductor pattern,
a first electrode on one end of the diode semiconductor pattern along the first direction, a second electrode on another end of the diode semiconductor pattern along the first direction, and
a diode gate electrode adjacent to the diode semiconductor pattern and extending in the second direction,
wherein the first electrode, the second electrode, and the diode gate electrode of the diode are connected to a static electricity discharge prevention circuit of the peripheral circuit structure.

19. The semiconductor device of claim 18, wherein:
one end of the diode semiconductor pattern along the first direction includes a first type of dopant, and
another end of the diode semiconductor pattern along the first direction includes a second type of dopant different from the first type of dopant.

20. The semiconductor device of claim 18, wherein the diode structure further comprises:
a plurality of diodes comprising the diode,
wherein diode gate electrodes of the plurality of diodes are connected to each other.
